(19) United States
(12) Patent Application Publication
(10) Pub. No.: US 2026/0033161 A1
(43) Pub. Date: Jan. 29, 2026

(54) DISPLAY PANEL, METHOD OF MANUFACTURING DISPLAY PANEL, AND DISPLAY DEVICE

(71) Applicant: HKC CORPORATION LIMITED, SHENZHEN (CN)

(72) Inventors: Xiaoxiao YUAN, SHENZHEN (CN); Chuan WU, SHENZHEN (CN); Zhonglin CAO, SHENZHEN (CN); Dongmei WEI, SHENZHEN (CN); Yao LI, SHENZHEN (CN); Jie CHEN, SHENZHEN (CN); Wenyu YI, SHENZHEN (CN); Fengzhen DANG, SHENZHEN (CN); Lidan YE, SHENZHEN (CN)

(73) Assignee: HKC CORPORATION LIMITED, SHENZHEN (CN)

(21) Appl. No.: 19/263,528

(22) Filed: Jul. 9, 2025

(30) Foreign Application Priority Data
Jul. 23, 2024 (CN) 202410996046.7

(51) Int. Cl. H10K 59/123; H10K 59/12

(52) U.S. Cl. CPC H10K 59/123; H10K 59/1201

(57) ABSTRACT

A display panel includes a light emitting carrier board and a silicon-based driver substrate bonded thereto. The light emitting carrier board includes a glass substrate, a light emitting device layer, and an isolation structure. The light emitting device layer comprises an anode layer, a light emitting function layer, and a common cathode layer that are sequentially stacked. The common cathode layer includes a cathode layer and a cathode connection portion electrically connected to the cathode layer. The anode layer, the light emitting function layer, and the cathode layer are stacked in a pixel region to form a light emitting device; the cathode connection portion is disposed in a non-pixel region; the isolation structure is disposed at a side of the light emitting device. At least some cathode connection portions are electrically connected to the silicon-based driver substrate through first connection holes.

### CROSS REFERENCE TO RELATED APPLICATIONS

The present application claims the priority of the Chinese patent application No. 202410996046.7, filed on Jul. 23, 2024, contents of which are incorporated herein by its entireties.

### TECHNICAL FIELD

Embodiments of the present disclosure relate to the technical field of displaying, and more specifically, to a display panel, a method of manufacturing a display panel, and a display device.

### BACKGROUND

Compared to the traditional Active-matrix organic light emitting diode (AMOLED) display technology, a silicon-based organic light emitting diode (OLED) micro-display takes a monocrystalline silicon chip as a base and is made from a mature complementary metal oxide semiconductor (CMOS) process. Therefore, the silicon-based OLED micro-display has smaller-sized pixels and has higher integration, such that the silicon-based OLED micro-display can be made into a near-eye display product comparable to a large-screen display, which has attracted widespread attention.

However, in a process of vaporizing sub-pixels, a silicon-based driver circuit layer may be affected.

### SUMMARY

The present disclosure provides a display panel, a method of manufacturing a display panel, and a display device, in order to solve the technical problem where a silicon-based driver circuit layer may be affected during a process of vaporizing sub-pixels.

In a first aspect, the present disclosure provides a display panel, having a displaying region. The displaying region includes a pixel region and a non-pixel region located at a side of the pixel region. The display panel includes the following.

A light emitting carrier board includes a glass substrate, a plurality of light emitting device layers, and a plurality of isolation structures. Each of the plurality of light emitting device layers comprises an anode layer, a light emitting function layer, and a common cathode layer that are sequentially stacked; the common cathode layer comprises a cathode layer and a cathode connection portion electrically connected to the cathode layer; the anode layer, the light emitting function layer, and the cathode layer are sequentially stacked in the pixel region to form one light emitting device; the cathode connection portion is disposed in the non-pixel region; each of the plurality of isolation structures is respectively disposed at a side of the light emitting device.

A silicon-based driver substrate is bonded to the light emitting carrier board.
the cathode connection portion of each of at least a portion of the plurality of light emitting device layers is electrically connected to the silicon-based driver substrate through at least one first connection hole; in a direction perpendicular to the glass substrate, the first connection hole sequentially extends through the isolation structure and the glass substrate.

In a second aspect, the present disclosure provides a method for manufacturing the display panel of the first aspect. The method includes:
providing a light emitting carrier board;
providing a silicon-based driver substrate; and
bonding the light emitting carrier board to the silicon-based driver substrate.

In a third aspect, the present disclosure provides a display device, including a motherboard and the display panel of the first aspect.

### BRIEF DESCRIPTION OF THE DRAWINGS

To more clearly illustrate technical solutions in the embodiments of the present disclosure or the related art, the accompanying drawings needed for describing the embodiments of the present disclosure or the related art will be briefly introduced in the following. Obviously, the drawings in the following description are only some embodiments of the present disclosure, and any ordinary skilled person in the art may obtain other drawings based on these drawings without creative work.

FIG. 1 is a structural schematic view of a display panel according to an embodiment of the present disclosure.

FIG. 2 is a structural schematic view of arrangement of a light emitting device and a first connection hole according to a first embodiment of the present disclosure.

FIG. 3 is a structural schematic view of arrangement of the light emitting device and the first connection hole according to a second embodiment of the present disclosure.

FIG. 4 is a structural schematic view of arrangement of the light emitting device and the first connection hole according to a third embodiment of the present disclosure.

FIG. 5 is a structural schematic view of arrangement of the light emitting device and the first connection hole according to a fourth embodiment of the present disclosure.

FIG. 6 is a structural schematic view of arrangement of the light emitting device and the first connection hole according to a fifth embodiment of the present disclosure.

FIG. 7 is a structural schematic view of arrangement of the light emitting device and the first connection hole according to a sixth embodiment of the present disclosure.

FIG. 8 is a flow chart of a method of manufacturing the display panel according to an embodiment of the present disclosure.

FIG. 9 is a structural schematic view of structures corresponding to operations S10 to S30 in FIG. 8.

FIG. 10 is a structural schematic view of a display device according to an embodiment of the present disclosure.

### REFERENCE NUMERALS IN THE DRAWINGS

100, display panel; 101, displaying region; 101A, pixel region; 101B, non-pixel region; 102, bezel region; 10, light emitting carrier board; 11, glass substrate; 12, light emitting device layer; 121, anode layer; 122, light emitting function layer; 123, common cathode layer; 123A, cathode layer; 123B, cathode connection portion; 123C, cathode extension portion; 120, light emitting device; 13, first connection hole; 131, first hole portion; 132, second hole portion; 14, isolation structure, 15, second connection hole; 151, third hole portion; 152, fourth hole portion; 16, glass through hole; 17, extension electrode; 171, cathode extension electrode; 172, anode extension electrode; 18, encapsulation layer; 20, silicon-based driver substrate; 21, silicon substrate; 22, a drive circuit layer; 221, a cathode driver electrode; 222, an anode driver electrode; 200, a motherboard; 300, a display device; 400, a transient substrate.

### DETAILED DESCRIPTIONS

Technical solutions of the present disclosure will be described in detail by referring to the accompanying drawings.

In the following description, specific details such as particular system structures, interfaces, techniques, and the like are provided for the purpose of illustration and not for limitation, in order to provide a thorough understanding of the present disclosure.

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

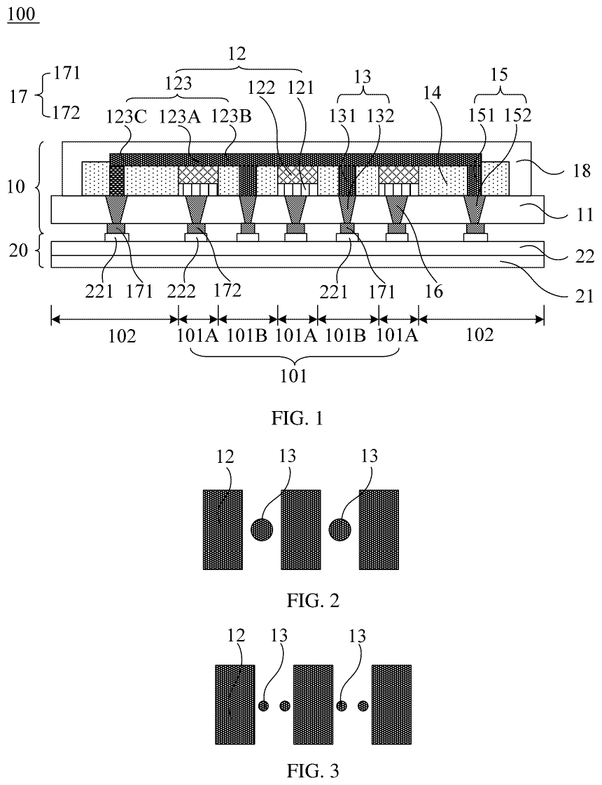

As shown in FIG. 1, FIG. 1 is a structural schematic view of a display panel according to an embodiment of the present disclosure.

The present disclosure provides a display panel 100. The display panel 100 has a displaying region 101. The displaying region 101 includes a pixel region 101A and a non-pixel region 101B disposed at a side of the pixel region 101A. The display panel 100 includes a light emitting carrier board 10 and a silicon-based driver substrate 20. The light emitting carrier board 10 includes a glass substrate 11, a plurality of light emitting device layers 12, and a plurality of isolation structures 14. Each of the plurality of light emitting device layers 12 includes an anode layer 121, a light emitting function layer 122, and a common cathode layer 123 that are sequentially stacked. The common cathode layer 123 includes a cathode layer 123A and a cathode connection portion 123B electrically connected to the cathode layer 123A. The anode layer 121, the light emitting function layer 122, and the cathode layer 123A are sequentially stacked in the pixel region 101A to form light emitting devices 120. The cathode connection portion 123B is located in the non-pixel region 101B. The isolation structure 14 is disposed at a side of the light emitting device 120. The silicon-based driver substrate 20 is bonded to the light emitting carrier board 10. The cathode connection portion 123B of at least a portion of the plurality of light emitting device layers 12 is electrically connected to the silicon-based driver substrate 20 through a first connection hole 13. In a direction perpendicular to the glass substrate 11, the first connection hole 13 sequentially extends through the isolation structure 14 and the glass substrate 11.

The light emitting carrier board 10 arranged with the light emitting device 120 and the silicon-based driver substrate 20 are prepared independently from each other and then are bonded to each other for connection. In this way, the light emitting device 120 does not need to be directly prepared on the silicon-based driver substrate 20, an impact on a driver circuit layer 22 in the silicon-based driver substrate 20, during the process of vaporizing the light emitting device 120, may be reduced, such that any loss caused by subsequent process errors may be reduced, and a manufacturing cost of the silicon-based driver substrate 20 is reduced. Furthermore, the cathode connection portion 123B in the displaying region 101 is electrically connected to the silicon-based driver substrate 20 through the first connection hole 13, and in this way, a resistance of the common cathode layer 123 on the entire surface within the displaying region 101 is reduced, resolving the problem of a voltage drop, and improving homogeneity of the cathode layer 123A.

The anode layer 121, the light emitting function layer 122, and the cathode layer 123A are sequentially stacked at a side of the glass substrate 11 to form the light emitting device 120 in the pixel region 101A. That is, the light emitting device 120 is vaporized and then arranged on the glass substrate 11, instead of being directly vaporized on the silicon-based driver substrate 20. In this way, the light emitting device 120 may be prepared independent from the silicon-based driver substrate 20. Therefore, during manufacturing the light emitting device 120, an influence on the silicon-based driver substrate 20 is reduced.

It should be noted that the common cathode layer 123 may be a whole surface structure.

In an embodiment, the light emitting device 120 may be an organic light emitting diode (OLED).

A shape, a size, and arrangement of light emitting devices 120 are not limited herein and can be determined according to actual needs. The display panel 100 includes a plurality of light emitting devices 120 that emit light in different colors. Colors of light emitted from each of the plurality of light emitting devices 120 are not limited herein and can be determined according to the actual needs.

In the present embodiment, each light emitting device 120 is rectangular in a direction parallel to the glass substrate 11. The plurality of light emitting devices 120 are arranged in an array.

In other embodiments, in the direction parallel to the glass substrate 11, the light emitting device 120 may be circular, polygonal, such as being triangular, trapezoidal, and the like. Alternatively, the light emitting device 120 may be irregularly shaped.

The cathode connection portion 123B is disposed at a side of the cathode layer 123A to achieve electrical connection between two adjacent cathode layers 123A. The cathode connection portion 123B and the isolation structure 14 disposed in the displaying region 101 are in one-to-one correspondence with each other. The cathode connection portion 123B is disposed at a side of the isolation structure 14 away from the glass substrate 11 and covers the corresponding isolation structure 14.

At least a portion of cathode connection portions 123B are electrically connected to the silicon-based driver substrate 20 through the first connection hole 13. In other words, the cathode connection portion 123B of a portion of the plurality of light emitting device layers 12 is electrically connected to the silicon-based driver substrate 20 through the first connection hole 13, and the cathode connection portion 123B of another portion of the plurality of light emitting device layers 12 is electrically connected to the silicon-based driver substrate 20 without passing through the first connection hole 13; or the cathode connection portion 123B of each of the plurality of light emitting device layers 12 is electrically connected to the silicon-based driver substrate 20 through first connection hole 13. The present disclosure does not limit a specific situation, a manner in which the electrical connection is achieved can be determined according to actual needs.

In some embodiments, for at least some of a plurality of cathode connection portions 123B of the plurality of light emitting device layers 12, one cathode connection portion 123B is arranged corresponding to at least one first connection hole 13. In other words, for any cathode connection portion 123B electrically connected to the silicon-based driver substrate 20 through the first connection holes 13, one cathode connection portion 123B is electrically connected to the silicon-based driver substrate 20 through one or more of first connection holes 13. As the number of first connection holes 13 increases, a resistance of the common cathode layer 123 electrically connected to the first connection holes 13 is reduced, and an effect of preventing the voltage drop is better.

In other embodiments, for the at least some of the plurality of cathode connection portions 123B of the plurality of light emitting device layers 12, more than one cathode connection portions 123B share one first connection hole 13. In other words, for all cathode connection portions 123B electrically connected to the silicon-based driver substrate 20 via the first connection hole 13, more than one adjacent cathode connection portions 123B are electrically connected to the silicon-based driver substrate 20 via one first connection hole 13. Since the more than one cathode connection portions 123B share one first connection hole 13, a diameter of the first connection hole 13 may be appropriately enlarged, which may simplify a process of preparing the first connection hole 13, and a product yield may be improved.

It should be understood that the more than one cathode connection portions 123B share one first connection hole 13, and a range in which the diameter of the first connection hole 13 can be adjusted may be related to arrangement of the plurality of light emitting devices 120 and related to a spacing between adjacent light emitting devices 120.

In the present embodiment, for all the cathode connection portions 123B electrically connected to the silicon-based driver substrate 20 via the first connection holes 13, one cathode connection portion 123B is arranged corresponding to one first connection hole 13.

In the direction parallel to the glass substrate 11, a cross section of the first connection hole 13 may be rectangular, circular, triangular, or polygonal.

In the present embodiment, in the direction parallel to the glass substrate 11, the cross section of the first connection hole 13 may be circular, facilitating preparation of the first connection hole 13.

A portion of the first connection hole 13 penetrating the isolation structure 14 is defined as a first hole portion 131, and another portion of the first connection hole 13 penetrating the glass substrate 11 is defined as a second hole portion 132. The first hole portion 131 has a diameter of 5 μm to 15 μm, and the second hole portion 132 has a diameter of 5 μm to 15 μm. A size relationship between the first hole portion 131 and the second hole portion 132 is not limited herein, as long as electrical connection can be achieved between the first hole portion 131 and the second hole portion 132.

It should be noted that the first hole portion 131 and the second hole portion 132 in the present embodiment are not prepared by one process, but are prepared by a plurality of processes. That is, a shape of the first hole portion 131 and a shape of the second hole portion 132 may be or may not be the same to each other, and the shapes can be determined according to actual needs.

A conductive material filled in the first hole portion 131 and a conductive material filled in the second hole portion 132 are not limited herein and can be determined according to actual needs.

In the present embodiment, the conductive material filled in the first hole portion 131 is different from the conductive material filled in the second hole portion 132. The cathode connection portion 123B may serve as the conductive material filled in the first hole portion 131, and that is, the cathode connection portion 123B covers a hole wall of the first hole portion 131. The conductive material filled in the second hole portion 132 is the same as a material of the anode layer 121, such that the conductive material filled in the second hole portion 132 and the anode layer 121 can be obtained by performing one preparation process, and therefore, manufacturing is simplified.

It should be understood that in other embodiments, the first hole portion 131 is filled with the conductive material, and the cathode connection portion 123B covers an end opening at a side of the first hole portion 131 away from the glass substrate 11.

In some embodiments, the light emitting device 120 is in a shape of rectangle in the direction parallel to the glass substrate 11. The first connection hole 13 is located at a side edge of the rectangle. Alternatively, the first connection hole 13 is located at a corner region of the rectangle. Alternatively, a portion of the first connection hole 13 is located at the side of edge of the rectangle, and another portion of the first connection hole 13 is located at the corner region of the rectangle.

As shown in FIGS. 1 to 4, FIG. 2 is a structural schematic view of arrangement of light emitting devices and first connection holes according to a first embodiment of the present disclosure;

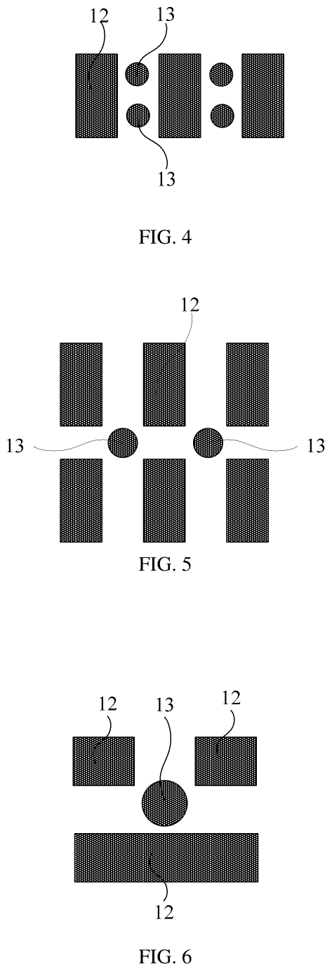

FIG. 3 is a structural schematic view of arrangement of the light emitting devices and the first connection holes according to a second embodiment of the present disclosure; and FIG. 4 is a structural schematic view of arrangement of the light emitting devices and the first connection holes according to a third embodiment of the present disclosure.

In the present embodiment, at least one first connection hole 13 is disposed at a long side edge of the rectangle and is disposed between two adjacent light emitting devices 12.

In a specific embodiment, the diameter of the first connection hole 13 is 10 μm.

In other embodiments, the first connection hole 13 may be disposed at a short side edge of the rectangle, or the first connection hole 13 may be disposed at each side edge of the rectangle. One cathode connection portion 123B may correspond to two first connection holes 13, and the two first connection holes 13 are disposed at one side edge of the rectangle and are disposed side-by-side along either the long side edge or the short side edge of the rectangle (shown in FIGS. 3 and 4).

It should be appreciated that when one cathode connection portion 123B is arranged corresponding to more than one first connection holes 13 and the more than one first connection holes 13 are located at one side edge of the rectangle, the diameter of the first connection hole 13 may be appropriately reduced in order to avoid reducing too much of an area of the pixel region 101A in which the light emitting devices 12 are located.

It should be noted that the diameter in the embodiments of the present disclosure refers to the diameter of the hole.

It should be understood that in other embodiments, the light emitting device 120 may be polygonal or in other shapes in the direction parallel to the glass substrate 11.

The isolation structure 14 has insulating performance and is configured to isolate the light emitting devices 120 from each other to prevent optical cross interference. A material of the isolation structure 14 is not limited herein and can be determined according to actual needs.

The display panel 100 further includes a bezel region 102 disposed at a side of the displaying region 101. A portion of the isolation structure 14 is disposed in the non-pixel region 101A, and another portion of the isolation structure 14 is disposed in the bezel region 102.

The common cathode layer 123 further includes a cathode extension portion 123C electrically connected to the cathode layer 123A. The cathode extension portion 123C is disposed in the bezel region 102, and the cathode extension portion 123C is electrically connected, through a second connection hole 15, to the silicon-based driver substrate 20. In a direction perpendicular to the glass substrate 11, the second connection hole 15 sequentially extends through the isolation structure 14 and the glass substrate 11.

A portion of the second connection hole 15 extending through the isolation structure 14 is defined as a third hole portion 151, and another portion of the second connection hole 15 extending through the glass substrate 11 is defined as a fourth hole portion 152. A size relationship between the third hole portion 151 and the fourth hole portion 152 is not limited herein, as long as electrical connection can be achieved between the third hole portion 151 and the fourth hole portion 152.

A conductive material filled in the third hole portion 151 and a conductive material filled in the fourth hole portion 152 are not limited herein and can be determined according to actual needs.

In the present embodiment, the conductive material filled in the third hole portion 151 may be different from the conductive material filled in the fourth hole portion 152. The conductive material filled in the third hole portion 151 may be the same as a material of the cathode extension portion 123C, such that the conductive material filled in the third hole portion 151 and the common cathode layer 123 may be obtained by performing one preparation process, such that manufacturing may be simplified. The conductive material filled in the fourth hole portion 152 may be the same as a material of the anode layer 121, such that the conductive material filled in the fourth hole portion 152 and the anode layer 121 can be obtained by performing one preparation process, and the manufacturing may be simplified.

It is to be noted that both the first connection hole 13 and the second connection hole 15 are configured to electrically connect the common cathode layer 123 to the silicon-based driver substrate 20, but the first connection hole 13 and the second connection hole 15 are located at different locations. The first connection hole 13 is located in the non-pixel region 101B, and the second connection hole 15 is located in the bezel region 102.

The silicon-based driver substrate 20 includes a silicon substrate 21 and a driver circuit layer 22. The driver circuit layer 22 is disposed on a side of the silicon substrate 21 near the light emitting carrier board 10. The silicon substrate 21 refers to a substrate board taking monocrystalline silicon as a base. The driver circuit layer 22 includes an active drive circuit (not shown in the drawing) integrated on the silicon substrate 21 based on a CMOS process.

The anode layer 121 of the light emitting device 120 is electrically connected to the silicon-based driver substrate 20 through a glass through hole 16 defined in the glass substrate 11. A conductive material filled in the glass through hole 16 is not limited herein and can be determined according to actual needs.

The light emitting carrier board 10 further includes an extension electrode 17. The extension electrode 17 is disposed on a side of the glass substrate 11 away from the light emitting device layer 12. The extension electrode 17 includes an anode extension electrode 172 and a cathode extension electrode 171.

The cathode connection portion 123B is electrically connected to the cathode expansion electrode 171 through the first connection hole 13, and the cathode expansion electrode 171 is bonded to a cathode driver electrode 221 of the driver circuit layer 22.

The anode layer 121 is electrically connected to the anode extension electrode 172 through the glass through hole 16, and the anode extension electrode 172 is bonded to an anode driver electrode 222 of the driver circuit layer 22.

Further, the cathode extension portion 123C is electrically connected to the cathode extension electrode 171 through the second connection hole, and the cathode extension electrode 171 is bonded to the cathode driver electrode 221 of the driver circuit layer 22.

That is, the extension electrode 17 on the light emitting carrier board 10 is bonded correspondingly to the driver electrode (i.e., the anode driving electrode 222 and the cathode driving electrode 221) on the silicon-based driving substrate 20 to achieve bonding connection between the light emitting carrier board 10 and the silicon-based driver substrate 20.

The driver circuit layer 22 provides a common voltage to the common cathode layer 123 via the cathode driver electrode 221 and provides an operating voltage to the anode layer 121 of the light emitting device 120 via the anode driver electrode 222, so as to drive the light emitting device 120 to emit light.

In the present embodiment, the glass through hole 16, the second hole portion 132, and the fourth hole portion 152 are filled with a same conductive material, such that conductive materials filled in all through holes defined in the glass substrate 11 can be obtained by performing one preparation process, and the manufacturing is simplified. Furthermore, the glass through hole 16, the second hole portion 132 and the fourth hole portion 152 can be prepared by performing one preparation process, and the manufacturing is simplified.

The light emitting carrier board 10 further includes an encapsulation layer 18. The encapsulation layer 18 is arranged on a side of the light emitting device 120 away from the glass substrate 11 to encapsulate the light emitting device 120. A structure and a material of the encapsulation layer 18 are not limited herein and can be determined according to the actual needs. A surface of a side of the encapsulation layer 18 away from the glass substrate 11 is flattened.

As shown in FIGS. 1 and 5, FIG. 5 is a structural schematic view of arrangement of the light emitting devices and the first connection holes according to a fourth embodiment of the present disclosure.

In the fourth embodiment, the light emitting devices 120 and the first connection holes 13 have substantially similar structures as those in the first embodiment, however, in the present embodiment, the first connection holes 13 are located at corner regions of the rectangle.

In the present embodiment, the light emitting device 120 is rectangular in the direction parallel to the glass substrate 11.

The light emitting devices 120 are arranged in an array. In the direction parallel to the glass substrate 11, the first connection hole 13 is located in an overlapping region of adjacent cathode connection portions 123B. Specifically, as shown in FIG. 5, the first connection hole 13 is located in an overlapping region of four adjacent cathode connection portions 123B in the direction parallel to the glass substrate 11. That is, the four cathode connection portions 123B share one first connection hole 13.

In an embodiment, the diameter of the first connection hole 13 is 15 μm.

Compared to the first embodiment, the first connection hole 13 in the present embodiment is configured in such a manner that the spacing between adjacent light emitting devices 120 can be reduced. The area of the pixel region 101A in which the light emitting devices 120 are located is not reduced as much as possible, ensuring that the cathode connection portions 123B can be electrically connected to the silicon-based driver substrate 20 through the first connection hole 13. Furthermore, the diameter of the first connection hole 13 is increased to various extent, simplifying difficulty of preparing the first connection hole 13, such that the product yield is improved, and product reliability is improved.

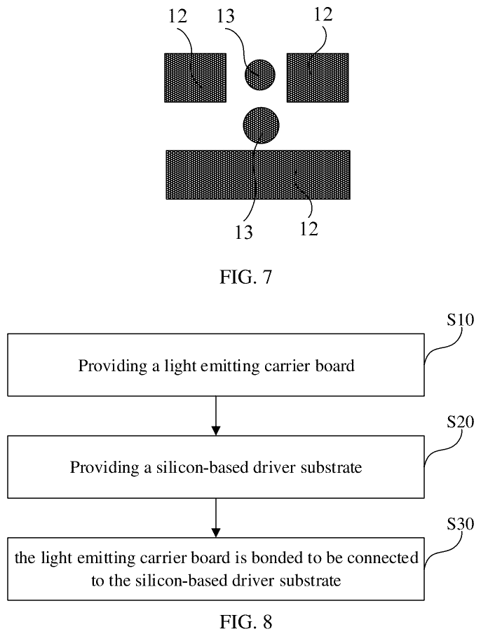

As shown in FIG. 1, FIG. 6 and FIG. 7, FIG. 6 is a structural schematic view of arrangement of the light emitting devices and the first connection holes according to a fifth embodiment of the present disclosure; and FIG. 7 is a structural schematic view of arrangement of the light emitting devices and the first connection holes according to a sixth embodiment of the present disclosure.

In the fifth embodiment, the light emitting devices 120 and the first connection holes 13 have substantially similar structures compared to those in the fourth embodiment. However, in the present embodiment, a portion of the first connection hole 13 is located on the side edge of the rectangle, and another portion of the first connection hole 13 is located at the corner region of another rectangle.

In the present embodiment, three light emitting devices 120 are combined to form one repeating unit in a shape of a rectangle. A plurality of repeating units are arranged in an array.

In each of the plurality of repeating units, two light emitting devices 120 are arranged side by side along a row direction of the plurality of repeating units and are disposed on one side of the rest one light emitting device 120 along a column direction of the plurality of repeating units. In each of the plurality of repeating units, three mutually adjacent cathode connection portions 123B share one first connection hole 13.

The first connection hole 13 is located at corner regions of two rectangles formed by the two light emitting devices 120 that are disposed side by side, and is also located at a side edge of a rectangle formed by the rest one light emitting device 120.

In an embodiment, the diameter of the first connection hole 13 is 15 μm.

The first connection hole 13 in the present embodiment is configured in such a way that the spacing between adjacent light emitting devices 120 can be reduced. The area of the pixel region 101A in which the light emitting devices 120 are located is not reduced as much as possible, ensuring that the cathode connection portions 123B can be electrically connected to the silicon-based driver substrate 20 through the first connection hole 13. The arrangement of the light emitting devices 120 and the first connection holes 13 in the present embodiment is different from that in the second embodiment.

It should be understood that in the other embodiments, in each repeating unit, a portion of the first connection hole 13 is located at the side edge of the rectangle, and another portion of the first connection hole 13 is located at the corner region of the rectangle (see FIG. 7). The light emitting devices 120 can be arranged in various manners, the first connection holes 13 can be arranged in various manners. The present disclosure does not limit specific arrangement manners, which may be determined according to the actual needs.

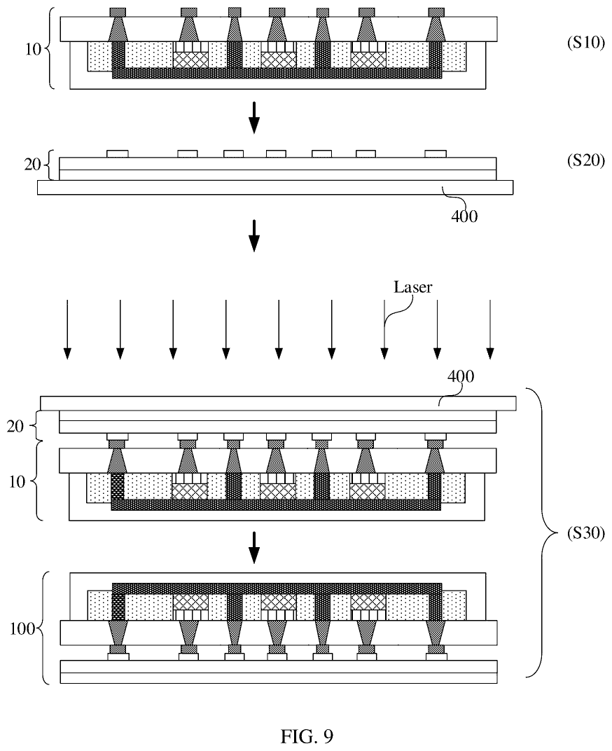

As shown in FIG. 1, FIG. 8 and FIG. 9, FIG. 8 is a flow chart of a method of manufacturing the display panel according to an embodiment of the present disclosure; FIG. 9 is a structural schematic view of structures corresponding to operations S10 to S30 in FIG. 8.

The present application provides a method of manufacturing the display panel 100 as described above.

In an embodiment, the method for manufacturing the display panel specifically includes following operations.

In an operation S10, a light emitting carrier board is provided.

Specifically, the light emitting carrier board 10 as described above is provided, which will not be described herein and can be referred to the above description.

In an operation S20, a silicon-based driver substrate is provided.

Specifically, the silicon-based driver substrate 20 as described above is provided, which will not be described herein and can be referred to the above description.

It should be noted that the operations S10 and S20 in the present embodiment can be performed in any sequence. That is, the operation S20 may be performed before or simultaneously with the operation S10.

The silicon-based driver substrate 20 is arranged on a transient substrate 400, such that, in a subsequent operation, the silicon-based driver substrate 20 may be bonded to the light emitting carrier board 10 by transferring the transient substrate 400.

It should be understood that the light emitting carrier board 10 may be arranged on the transient substrate 400, such that, in the subsequent operation, the silicon-based driver substrate 20 may be bonded to the light emitting carrier board 10 by transferring the transient substrate 400.

In an operation S30, the light emitting carrier board is bonded to be connected to the silicon-based driver substrate.

Specifically, the light emitting carrier board 10 is aligned with the silicon-based driver substrate 20, and the extension electrodes 17 on the light emitting carrier board 10 are bonded correspondingly to the driver electrodes (i.e., the anode driver electrode 222 and the cathode driver electrode 221) on the silicon-based driver substrate 20 to enable the silicon-based driver substrate 20 to drive the light emitting carrier board 10 to emit light.

In an embodiment, the transient substrate 400 is transferred, such that the silicon-based driver substrate 20 on the transient substrate 400 is aligned with the light emitting carrier board 10, the laser is irradiated to enable the driver electrodes on the silicon-based driver substrate 20 to be one-to-one correspondingly bonded with the extension electrodes 17 on the light emitting carrier board 10. Furthermore, the transient substrate 400 is removed to obtain the display panel 100.

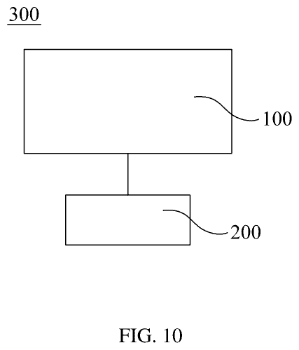

As shown in FIG. 10, FIG. 10 is a structural schematic view of a display device according to an embodiment of the present disclosure.

The present disclosure provides a display device 300. The display device 300 includes a motherboard 200 and the display panel 100 as described above. The display device 300 of the present embodiment is an AMOLED.

The motherboard 200 is electrically connected to the display panel 100, and the motherboard 200 is configured to transmit various required signals to the display panel 100 to control the display panel 100 to display an image. For example, the various required signals may be a clock signal (CK), a low potential signal (Vss), a power supply voltage signal (VDD), and a data signal (Data) that are required for driving the circuit layer.

According to the present disclosure, a display panel, a method of manufacturing the display panel, and a display device are provided. The display panel has a displaying region. The displaying region includes a pixel region and a non-pixel region disposed at the side of the pixel region. The display panel includes a light emitting carrier board and a silicon-based driver substrate. The light emitting carrier board includes a glass substrate, a light emitting device layer, and an isolation structure. The light emitting device layer includes an anode layer, a light emitting function layer, and a common cathode layer that are sequentially stacked. The common cathode layer includes a cathode layer and a cathode connection portion electrically connected to the cathode layer. The anode layer, the light emitting function layer, and the cathode layer are sequentially stacked in the pixel region to form the light emitting device. The cathode connection portion is disposed in the non-pixel region. The isolation structure is disposed at the side of the light emitting device. The silicon-based driver substrate is bonded to the light emitting carrier board. At least a portion of the cathode connection portion is electrically connected to the silicon-based driver substrate through a first connection hole. In a direction perpendicular to the glass substrate, the first connection hole extends through the isolation structure and the glass substrate sequentially. The light emitting carrier board arranged with the light emitting device and the silicon-based driver substrate are prepared independently from each other and then are bonded to each other for connection. In this way, the light emitting device does not need to be directly prepared on the silicon-based driver substrate, an impact on the driver circuit layer in the silicon-based driver substrate, during the process of vaporizing the light emitting device, may be reduced, such that any loss caused by subsequent process errors may be reduced, and a manufacturing cost of the silicon-based driver substrate is reduced. Furthermore, the cathode connection portion in the displaying region is electrically connected to the silicon-based driver substrate through the first connection hole, and in this way, a resistance of the common cathode layer on the entire surface within the displaying region is reduced, resolving the problem of a voltage drop, and improving homogeneity of the cathode layer.

In the above embodiments, description of each embodiment has its own focus, and parts that are not detailed in one embodiment may be referred to the relevant descriptions of other embodiments.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, having a displaying region, the displaying region comprising a pixel region and a non-pixel region located at a side of the pixel region; wherein the display panel comprises:
a light emitting carrier board, comprising a glass substrate, a plurality of light emitting device layers, and a plurality of isolation structures, wherein each of the plurality of light emitting device layers comprises an anode layer, a light emitting function layer, and a common cathode layer that are sequentially stacked; the common cathode layer comprises a cathode layer and a cathode connection portion electrically connected to the cathode layer; the anode layer, the light emitting function layer, and the cathode layer are sequentially stacked in the pixel region to form one light emitting device; the cathode connection portion is disposed in the non-pixel region; each of the plurality of isolation structures is respectively disposed at a side of the light emitting device; and
a silicon-based driver substrate, bonded to the light emitting carrier board;
wherein the cathode connection portion of each of at least a portion of the plurality of light emitting device layers is electrically connected to the silicon-based driver substrate through at least one first connection hole; in a direction perpendicular to the glass substrate, the first connection hole sequentially extends through the isolation structure and the glass substrate.

2. The display panel according to claim 1, wherein, when the cathode connection portion of each of at least a portion of the plurality of light emitting device layers is electrically connected to the silicon-based driver substrate through the first connection hole, and when the at least one first connection hole is a plurality of first connection holes, one cathode connection portion is arranged corresponding to at least one of the plurality of first connection holes.

3. The display panel according to claim 1, wherein when the cathode connection portion of each of at least a portion of the plurality of light emitting device layers is electrically connected to the silicon-based driver substrate through the first connection hole, the cathode connection portion of each of more than one of the at least a portion of the plurality of light emitting device layers share one of the at least one first connection hole first connection hole.

4. The display panel according to claim 1, wherein, in a direction parallel to the glass substrate, each of the plurality of light emitting devices is in a shape of a rectangle;
wherein, the at least one first connection hole is located at a side edge of the rectangle; or
the at least one first connection hole is located in a corner region of the rectangle; or
a portion of the at least one first connection hole is located at a side edge of the rectangle of one of the plurality of light emitting devices, and another portion of the at least one first connection hole is located at a corner region of the rectangle of another one of the plurality of light emitting devices.

5. The display panel according to claim 1, wherein, for each of the at least one first connection hole, a portion of the first connection hole penetrating a respective of the plurality of isolation structure is a first hole portion, and another portion of the first connection hole penetrating the glass substrate is a second hole portion; the first hole portion has a diameter of 5 μm to 15 μm, and the second hole portion has a diameter of 5 μm to 15 μm.

6. The display panel according to claim 1, wherein the display panel further comprises a bezel region located at a side of the displaying region; the common cathode layer further comprises a cathode extension portion electrically connected to the cathode layer; the cathode extension portion is located in the bezel region; the cathode extension portion is electrically connected, via a second connection hole, to the silicone-based driver substrate; in a direction perpendicular to the glass substrate, the second connection hole sequentially extends through the isolation structure and the glass substrate.

7. The display panel according to claim 1, wherein the silicon-based driver substrate comprises a silicon substrate and a driver circuit layer; the driver circuit layer is arranged on a side of the silicon substrate near the light emitting carrier board; the anode layer of the light emitting device is electrically connected to the silicon-based driver substrate through a glass through hole defined in the glass substrate.

8. The display panel according to claim 7, wherein the light emitting carrier board further comprises an extension electrode, the extension electrode is disposed on a side of the glass substrate away from the plurality of light emitting device layers; the extension electrode comprises an anode extension electrode and a cathode extension electrode;
the cathode connection portion is electrically connected to the cathode extension electrode through the first connection hole, and the cathode extension electrode is bonded to a cathode driver electrode of the drive circuit layer;
the anode layer is electrically connected to the anode extension electrode through the glass through hole, the anode extension electrode is bonded to an anode driver electrode of the drive circuit layer.

9. A method for manufacturing a display panel, wherein the method comprises:
providing a light emitting carrier board;
providing a silicon-based driver substrate;
bonding the light emitting carrier board to the silicon-based driver substrate,
wherein the display panel has a displaying region, the displaying region comprises a pixel region and a non-pixel region located at a side of the pixel region;
wherein the light emitting carrier board comprises a glass substrate, a plurality of light emitting device layers, and a plurality of isolation structures; each of the plurality of light emitting device layers comprises an anode layer, a light emitting function layer, and a common cathode layer that are sequentially stacked; the common cathode layer comprises a cathode layer and a cathode connection portion electrically connected to the cathode layer; the anode layer, the light emitting function layer, and the cathode layer are sequentially stacked in the pixel region to form one light emitting device; the cathode connection portion is disposed in the non-pixel region; each of the plurality of isolation structures is respectively disposed at a side of the light emitting device; and
the cathode connection portion of each of at least a portion of the plurality of light emitting device layers is electrically connected to the silicon-based driver substrate through at least one first connection hole; in a direction perpendicular to the glass substrate, the first connection hole sequentially extends through the isolation structure and the glass substrate.

10. The method for manufacturing the display panel according to claim 9, wherein,
when the cathode connection portion of each of at least a portion of the plurality of light emitting device layers is electrically connected to the silicon-based driver substrate through the first connection hole, and when the at least one first connection hole is a plurality of first connection holes, one cathode connection portion is arranged corresponding to at least one of the plurality of first connection holes.

11. The method for manufacturing the display panel according to claim 9, wherein when the cathode connection portion of each of at least a portion of the plurality of light emitting device layers is electrically connected to the silicon-based driver substrate through the first connection hole, the cathode connection portion of each of more than one of the at least a portion of the plurality of light emitting device layers share one of the at least one first connection hole first connection hole.

12. The method for manufacturing the display panel according to claim 9, wherein, in a direction parallel to the glass substrate, each of the plurality of light emitting devices is in a shape of a rectangle;
wherein, the at least one first connection hole is located at a side edge of the rectangle; or
the at least one first connection hole is located in a corner region of the rectangle; or
a portion of the at least one first connection hole is located at a side edge of the rectangle of one of the plurality of light emitting devices, and another portion of the at least one first connection hole is located at a corner region of the rectangle of another one of the plurality of light emitting devices.

13. A display device, comprising a motherboard and a display panel;
wherein the display panel has a displaying region, the displaying region comprises a pixel region and a non-pixel region located at a side of the pixel region; wherein the display panel comprises:
a light emitting carrier board, comprising a glass substrate, a plurality of light emitting device layers, and a plurality of isolation structures, wherein each of the plurality of light emitting device layers comprises an anode layer, a light emitting function layer, and a common cathode layer that are sequentially stacked; the common cathode layer comprises a cathode layer and a cathode connection portion electrically connected to the cathode layer; the anode layer, the light emitting function layer, and the cathode layer are sequentially stacked in the pixel region to form one light emitting device; the cathode connection portion is disposed in the non-pixel region; each of the plurality of isolation structures is respectively disposed at a side of the light emitting device; and
a silicon-based driver substrate, bonded to the light emitting carrier board;
wherein the cathode connection portion of each of at least a portion of the plurality of light emitting device layers is electrically connected to the silicon-based driver substrate through at least one first connection hole; in a direction perpendicular to the glass substrate, the first connection hole sequentially extends through the isolation structure and the glass substrate.

14. The display device according to claim 13, wherein when the cathode connection portion of each of at least a portion of the plurality of light emitting device layers is electrically connected to the silicon-based driver substrate through the first connection hole, and when the at least one first connection hole is a plurality of first connection holes, one cathode connection portion is arranged corresponding to at least one of the plurality of first connection holes.

15. The display device according to claim 13, wherein when the cathode connection portion of each of at least a portion of the plurality of light emitting device layers is electrically connected to the silicon-based driver substrate through the first connection hole, the cathode connection portion of each of more than one of the at least a portion of the plurality of light emitting device layers share one of the at least one first connection hole first connection hole.

16. The display device according to claim 13, wherein, in a direction parallel to the glass substrate, each of the plurality of light emitting devices is in a shape of a rectangle;
wherein, the at least one first connection hole is located at a side edge of the rectangle; or
the at least one first connection hole is located in a corner region of the rectangle; or
a portion of the at least one first connection hole is located at a side edge of the rectangle of one of the plurality of light emitting devices, and another portion of the at least one first connection hole is located at a corner region of the rectangle of another one of the plurality of light emitting devices.

17. The display device according to claim 13, wherein, for each of the at least one first connection hole, a portion of the first connection hole penetrating a respective of the plurality of isolation structure is a first hole portion, and another portion of the first connection hole penetrating the glass substrate is a second hole portion; the first hole portion has a diameter of 5 μm to 15 μm, and the second hole portion has a diameter of 5 μm to 15 μm.

18. The display device according to claim 13, wherein the display panel further comprises a bezel region located at a side of the displaying region; the common cathode layer further comprises a cathode extension portion electrically connected to the cathode layer; the cathode extension portion is located in the bezel region; the cathode extension portion is electrically connected, via a second connection hole, to the silicone-based driver substrate; in a direction perpendicular to the glass substrate, the second connection hole sequentially extends through the isolation structure and the glass substrate.

19. The display device according to claim 13, wherein the silicon-based driver substrate comprises a silicon substrate and a driver circuit layer; the driver circuit layer is arranged on a side of the silicon substrate near the light emitting carrier board; the anode layer of the light emitting device is electrically connected to the silicon-based driver substrate through a glass through hole defined in the glass substrate.

20. The display device according to claim 19, wherein the light emitting carrier board further comprises an extension electrode, the extension electrode is disposed on a side of the glass substrate away from the plurality of light emitting device layers; the extension electrode comprises an anode extension electrode and a cathode extension electrode;
the cathode connection portion is electrically connected to the cathode extension electrode through the first connection hole, and the cathode extension electrode is bonded to a cathode driver electrode of the drive circuit layer;
the anode layer is electrically connected to the anode extension electrode through the glass through hole, the anode extension electrode is bonded to an anode driver electrode of the drive circuit layer.
